(19) United States
(12) Patent Application Publication
(10) Pub. No.: US 2026/0101683 A1
(43) Pub. Date: Apr. 9, 2026

(54) FILM DEPOSITION METHOD AND FILM DEPOSITION APPARATUS

(71) Applicant: ULVAC, INC., Kanagawa (JP)

(72) Inventors: Mitsunori NORO, Kanagawa (JP); Shinya NAKAMURA, Kanagawa (JP); Shoichi TAKAI, Kanagawa (JP)

(73) Assignee: ULVAC, INC., Kanagawa (JP)

(21) Appl. No.: 19/112,764

(22) PCT Filed: Aug. 9, 2024
(86) PCT No.: PCT/JP2024/028625

§ 371 Date: Mar. 18, 2025

(30) Foreign Application Priority Data
Nov. 13, 2023 (JP) 2023-192826

(51) Int. Cl. H10P 14/45; C23C 14/18; C23C 14/34; H01J 37/32; H01J 37/34; H10P 14/40

(52) U.S. Cl. CPC H10P 14/45; C23C 14/185; C23C 14/345; H01J 37/32183; H01J 37/3426; H10P 14/412; H01J 2237/332

(57) ABSTRACT

A sputtering gas containing a rare gas is introduced into a vacuum chamber 1 of a vacuum atmosphere, an electric power with a negative potential is supplied to a target 2, a positive potential is applied to the reflector plate 4, a plasma is generated, and subsequently the supply of the sputtering gas is stopped, then the target is sputtered while a self-holding discharge under low pressure of plasma is generated. A high-frequency bias power is supplied from a high-frequency power source 61 through an impedance matching device 62 to a stage 5 on which an object to be deposited is mounted. An electron matcher having at least one variable reactor to be electronically controlled is used as an impedance matching device, and a high-frequency bias power is intermittently supplied to the stage at a predetermined frequency.

### TECHNICAL FIELD

The invention relates to a film deposition method and a film deposition apparatus. More particularly, the invention relates to a film deposition method and a film deposition apparatus for depositing a metal film on an inner surface of each of a plurality of micro-recessed parts formed in a surface of an object to be deposited with good coverage using SIS (Self Ionized Sputter) technology.

### BACKGROUND ART

A manufacturing process for a semiconductor device includes a step of depositing a metal film, such as a Cu film as a seed layer or a Ta film as an underlayer of the Cu film, on an inner surface (an inner side surface and an inner bottom surface) of each of a plurality of trenches as a micro-recessed part. A so-called self-ionized sputtering apparatus is used in such a step of depositing the metal film. The aforementioned apparatus includes: a vacuum chamber in which a target made of a metal such as Cu and Ta and an object to be deposited are disposed directly opposite to each other; on a premise that a direction from the target to a substrate is defined as downward, a magnetic field generator disposed above the target and generating a leakage magnetic field in a lower space below the target; a gas introducer introducing a sputtering gas containing a rare gas into the vacuum chamber; a sputtering power source supplying an electric power with a negative potential to the target; and a reflector plate disposed to surround the lower space below the target, to which a positive potential is applied. Also, a stage, on which the object to be deposited is mounted, is provided in the vacuum chamber. Then, the aforementioned apparatus is configured that a high-frequency bias power is continuously supplied from a high-frequency bias power source to the stage through an impedance matching device that matches an impedance of a plasma with an impedance on a side of a high-frequency bias power source.

When depositing each of the metal film using the aforementioned self-ionized sputtering apparatus, the sputtering gas is introduced into the vacuum chamber of a vacuum atmosphere, the electric power with the negative potential is supplied to the target, and the positive potential is supplied to the reflector plate. As a result, the plasma is generated in the lower space below the target and is confined in the lower space by the magnetic field generated by the magnetic field generator. In this state, if the introduction of the sputtering gas is stopped, a self-holding discharge under low pressure of plasma will generate. Then, ions or the like of the sputtering gas in the plasma collide with a sputtered surface of the target and are scattered from the target. In addition, Cu atoms approximately reflected by the reflector plate and ionized Cu ions are attracted with strong straightness to be deposited with strong straightness and then adhere to and accumulate on the surface of the object to be deposited. Thus, a Cu film is deposited.

Meanwhile, among the micro-recessed parts as an object to be deposited, there is one with a high aspect ratio and another in which an inner side surface (a side wall) is not flat (in other words, there are micro-unevenness). Besides, thinning of each metal film deposited on the inner side surface of each micro-recessed part (for example, a film thickness in a range of 300 Å-500 Å) is being developed. In these cases, if the Cu film is deposited by the aforementioned self-ionized sputtering apparatus, not only a so-called overhang will sometimes occur but also continuity of the Cu film (thin film) deposited on the inner side surface of each micro-recessed part will be sometimes impaired (side coverage is inferior). If the continuity of the Cu film is thus impaired, there will be an issue that Cu wiring cannot be embedded by a plating method in a subsequential step.

### Reference

Patent Document No. 1: JP2010-209453 A

### SUMMARY OF INVENTION

### Technical Problems

In light of the aforementioned problem, the invention provides a film deposition method and a film deposition apparatus that can deposit a metal film with continuity on the inner side surface of each micro-recessed part and with good coverage.

### Solution to Problems

In order to solve the aforementioned problem, a film deposition method of the invention for depositing a metal film on an inner surface of each of a plurality of micro-recessed parts formed in a surface of an object to be deposited, the object being disposed in a vacuum chamber, including, a step of sputtering a target made of a metal while generating a self-holding discharge under low pressure of plasma after successively introducing the sputtering gas containing a rare gas into a vacuum chamber of a vacuum atmosphere, supplying an electric power with a negative potential to the target, and then stopping the introduction of the sputtering gas; a step of a step of applying a positive potential to a reflector plate disposed to surround a space between the object to be deposited and the target; and a step of supplying a high-frequency bias power from a high-frequency bias power source to a stage, on which the object to be deposited is mounted, through an impedance matching device that matches an impedance of the plasma with an impedance on a side of the high-frequency bias power source, wherein in the supply of the high-frequency bias power, an electron matcher having at least one variable reactor to be electronically controlled is used as an impedance matching device, and the high-frequency bias power is intermittently supplied to the stage at a predetermined frequency.

Here, the electron matcher as an impedance matching device has a characteristic that can match those impedances in a relatively short time, such as a few ms, compared with a matcher that drives variable capacitors mechanically. In addition, it has been known that a high Vdc is instantaneously generated at the beginning of supply the high-frequency bias power source through the impedance matching device. Attracting to these matters, when the electron matcher is used as an impedance matching device and the high-frequency bias power is supplied to the stage, the invention adopts that the high-frequency bias power is intermittently supplied at the predetermined frequency.

According to this, not only metal atoms and ions of the metal atoms from the target side are adhered to the inner surface of each micro-recessed part, but also a metal film on an inner bottom surface (bottom) of each micro-recessed part is sputtered by the high Vdc instantaneously generated every supply of the high-frequency bias power, and thus sputtered particles adhere to and accumulate on the inner side surface of each micro-recessed part in a reverse direction to those from the target side. This allows the metal film to be deposited on the inner side surface of each micro-recessed part with continuity and good coverage, even if the inner side surface is not flat. In addition, if the supplied high-frequency bias power is varied, a height position from the inner bottom surface of each micro-recessed part, at which mainly re-sputtered particles adhere, can be regulated.

Furthermore, it was confirmed that when the high-frequency electric power is intermittently supplied at the predetermined frequency, occurrence of the overhang can be suppressed as much as possible. This is caused by the following: When the high-frequency bias power is continuously supplied to the stage while the reflector plate is applied to the positive potential, Cu ions that maintain strong straightness are attracted to the object to be deposited, and some of the Cu ions are attracted to the object to be deposited not only in a vertical direction opposite to a surface of the object to be deposited, but also in a state inclined to the vertical one (namely, makes incident diagonally to the object to be deposited); further, an electric field is liable to concentrate at corner parts between the surface of the object to be deposited and each micro-recessed part. In contrast, in the invention, such electric field concentration can be suppressed by intermittently supplying the high-frequency bias power. In addition, in an off-state of the supply of the high-frequency bias power, the attraction of the Cu ions to the object to be deposited is instantaneously eliminated, and whereby the tracks of the Cu ions are corrected to be incident in the vertical direction to the surface of the substrate. As a result, it is considered that the occurrence of the overhang is suppressed as much as possible.

On the other hand, as in the invention, in the case where the metal film is intentionally to be deposited on the inner side surface of each micro-recessed part with good coverage by re-sputtering the metal film accumulated on the inner bottom surface of each micro-recessed part, it is preferable for the metal film to be preferentially deposited on the inner bottom surface at the beginning. Hence, the invention adopts a configuration in which the supplying step of the aforementioned high-frequency bias power includes a first step of setting the high-frequency electric power to a first electric power (for example, in a range of 10 W to 100 W, depending on the aspect ratio of each micro-recessed part, preferably 50 W) at the beginning of the deposition and preferentially depositing the metal film on the inner bottom surface of each micro-recessed part, and a second step of changing to a second electric power (for example, in a range of 500 W to 900 W, preferably 700 W) larger than the first electric power and supplying the high-frequency electric power.

According to this, it can be reliably ensured that the metal film with the predetermined thickness is deposited on the inner side surface of each recessed part with continuity and good coverage. Incidentally, in a case where the aspect ratio of each micro-recessed part is equal to or greater than 3, the frequency when the high-frequency bias power is supplied intermittently should be set only in a range of 1 kHz to 20 kHz, and a duty ratio when the high-frequency bias power is supplied intermittently should be set only in a range of 50% to 90%. In addition, a ratio of a film thickness when the first electric power is applied to that when the second electric power is applied can be set, for example, 1:3. It should be noted that although it may be considered that when the high-frequency bias power is supplied, the high-frequency electric bias power is increased continuously or in stages, in a case where total deposition time is short (for example, 10 seconds or shorter), there will be an issue that the deposition time in a state where the high-frequency bias power is relatively small will be long and side coverage cannot be effectively increased. Therefore, in a case where the deposition time set depending on the thickness of the metal film to be deposited is short, it is preferable to change the high-frequency bias power in two stages.

In the invention, in a case where the metal film is either a Cu-containing film formed as a seed layer or a Ta-containing film formed as an underlayer of the Cu-containing film, it was confirmed that the Cu-containing film or the Ta-containing film with a relatively thin thickness (for example, a film thickness in a range of 200 Å to 700 Å) can be deposited on the inner side surface of each micro-recessed part with continuity of the film and good coverage. It should be noted that the “Cu-containing film” referred to in the application is defined as a film mainly containing Cu, which consists of a Cu element in an amount of 90at % or more, and that the “Ta-containing film” includes a nitride film, an oxide film, and an oxynitride film of Ta other than a pure Ta film.

Furthermore, in order to solve the aforementioned problem, a film deposition apparatus of the invention for depositing a metal film on an inner surface of each of a plurality of micro-recessed parts formed in a surface of an object to be deposited, the object being disposed in a vacuum chamber, including, a gas introducer introducing a sputtering gas containing a rare gas into a vacuum chamber of a vacuum atmosphere; a sputtering power source that supplies an electric power with a negative potential to a target made of a metal; a reflector plate that is disposed to surround a space between the object to be deposited and the target and to which a positive potential is applied; and a stage on which the object to be deposited is mounted and to which a high-frequency electric power is supplied from a high-frequency bias power source through an impedance matching device that matches an impedance of a plasma with an impedance on a side of the high-frequency bias power source. The metal film deposition apparatus is configured that after the plasma is generated in a space in front of a sputtered surface of the target, and while the introduction of the sputtering gas is stopped to generate a self-holding discharge under low pressure of plasma, the target is sputtered. In the film deposition apparatus, the impedance matching device is configured by an electron matcher having at least one variable reactor to be electronically controlled, the impedance matching device being configured that the high-frequency bias power source intermittently supplies the high-frequency bias power.

### BRIEF DESCRIPTION OF THE DRAWINGS

FIG. 1 is a cross-sectional view schematically showing a film deposition apparatus of an embodiment.

FIG. 2 is a view explaining supply of a high-frequency bias power at a time of deposition.

FIG. 3 FIGS. 3A and 3B are views explaining attraction of ionized sputtering particles to an object to be deposited.

FIG. 4 FIGS. 4A and 4B are SEM images of experimental results showing effects of the invention.

### DESCRIPTION OF EMBODIMENTS

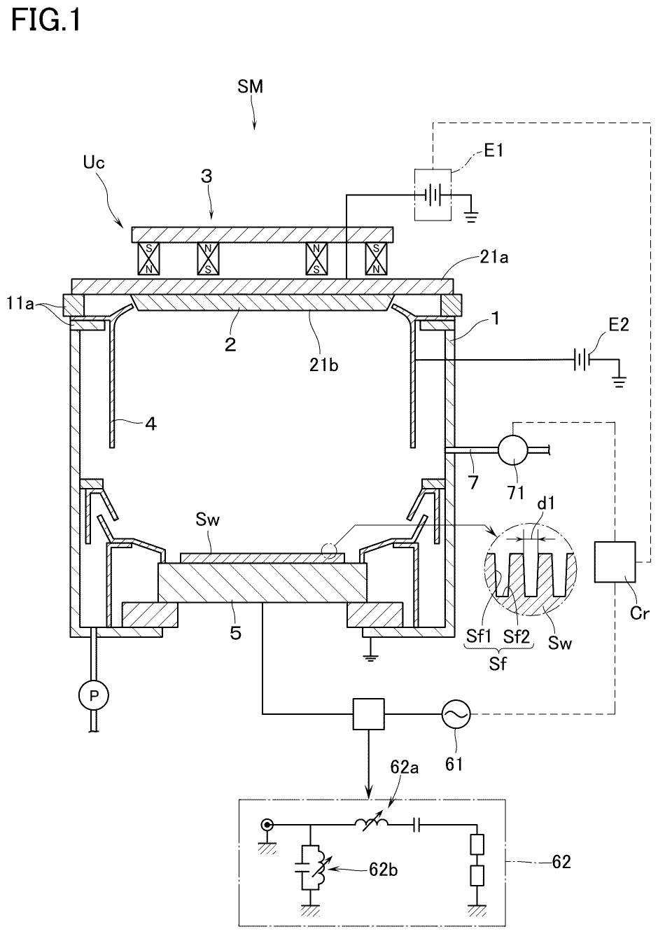

Now, referring to figures, an embodiment of a film deposition method and a film deposition apparatus of the invention will be described. In the embodiment, an object to be deposited is adopted to the one in which an insulating layer is formed on a surface of a semiconductor substrate such as a silicon wafer (hereinafter, referred to a “substrate Sw”), and a plurality of micro-recessed parts Sf is formed on the insulating layer in a predetermined pattern. In addition, in the embodiment, a self-ionized sputtering apparatus is adopted to the film deposition apparatus and deposits a metal film such as a Cu film or a Ta film on an inner side surface Sf1 and an inner bottom surface Sf2 of each micro-recessed part Sf with good coverage. Here, an inner surface of each micro-recessed part Sf is divided into the inner side surface Sf1 and the inner bottom surface Sf2. It should be noted that as a “micro-recessed part”, for example, one having an opening diameter d1 of 0.65 μm or smaller and an aspect ratio of 3 or more can be preferably used. In addition, a method of forming the micro-recessed part Sf can be used the conventional one, and therefore detailed descriptions are omitted. In the following, terms representing directions are defined as standard by FIG. 1 which depicts an installation posture of the self-ionized sputtering apparatus SM.

Referring to FIG. 1, the self-ionized sputtering apparatus SM includes a vacuum chamber 1 capable of forming a vacuum atmosphere. A cathode unit Uc is provided at an upper part of the vacuum chamber 1. The cathode unit Uc includes a target 2 made of copper or tantalum of predetermined purity and a magnet unit 3 disposed above the target 2. The target 2 is mounted on a backing plate 21a, and in this state, the target 2 is detachably attached to an upper opening of the vacuum chamber 1 through an insulating body 11a in a posture in which a sputtered surface 21b is directed downward. The magnet unit 3 generates a magnetic field in a lower space of the sputtered surface 21b, captures electrons or the like ionized below the sputtered surface 21b at a time of the sputtering, and effectively ionizes sputtered particles scattered from the target 2. Since a conventional unit can be used for the magnet unit 3, detailed description thereof is omitted. The target 2 is connected to an output from a first DC power source El as a sputtering power source and can be supplied with a predetermined electric power (18 kW or more) having a negative potential at the time of the deposition.

A reflector plate 4 with electrical conductivity is disposed in the vacuum chamber 1. The reflector plate 4 is a tubular member covering around the target 2 and extending downward, and a lower end of the reflector plate 4 is set to extend to a position of which a height is approximately half a TS distance between the target 2 and the substrate Sw. The reflector plate 4, which is connected to an output from a second DC power source 2 and to which a positive potential (5V to 100V) is applied during deposition, reflects the ionized sputtered particles, and assists release of the particles toward the substrate Sw with strong straightness. A stage 5 directly facing the target 2 is disposed at a lower part of the vacuum chamber 1. Not specifically illustrated or described, an electrostatic adsorption mechanism is provided with an upper surface of the stage 5, which can position, absorb, and hold the substrate Sw. In addition, a heating and cooling mechanism is incorporated into the stage 5, which can control within a temperature range without aggregation, for example, in a case of depositing a Cu film. An output from a high-frequency bias power source 61 is connected to the stage 5 through an impedance matching device 62 that matches an impedance of the plasma with an impedance on a side of the high-frequency bias power source 61 so that during the deposition, the high-frequency bias power is supplied to the stage 5 and further to the substrate Sw, and mainly ions of the metal atoms are actively attracted to a side of a substrate Sw.

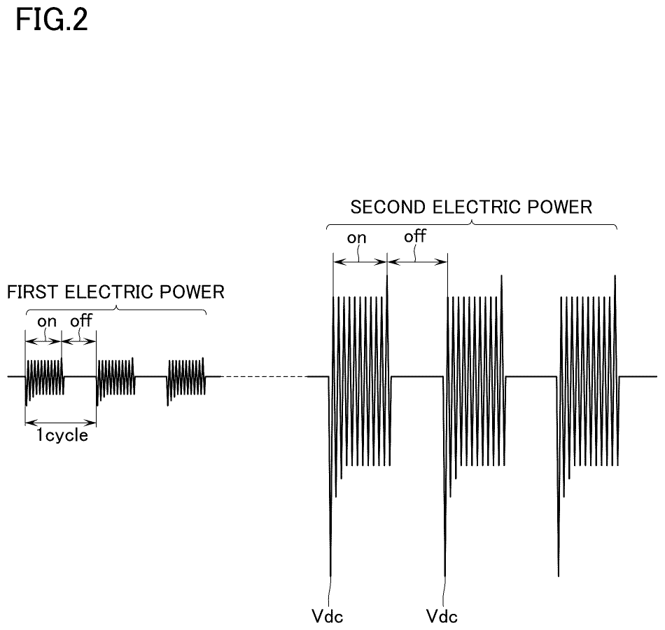

For example, the high-frequency bias power source 61 is used for a conventional power source that can output an electric power of 10 kW or less at a frequency of 13.56 MHz and includes a conventional pulse generating circuit (not shown). As shown in FIG. 2, the high-frequency bias power source 61 is configured to control turning on and off of the switching elements of the pulse generating circuit and to output the high-frequency bias power. As an impedance matching device 62, an electron matcher having variable reactors 62a, 62b to be electronically controlled, is used and can match the impedance of the plasma and the impedance on the side of the high-frequency bias power source 61 (referring to an enlarged portion shown in FIG. 1). Since a conventional electron matcher can be used as such an electron matcher, specific descriptions containing a control circuit and a control method are omitted.

A gas pipe 7, which configures a gas introducer and introduces the sputtering gas that is a rare gas such as argon, is connected to a side wall of the vacuum chamber 1. The gas introducer can introduce the sputtering gas, of which a flow rate is controlled by a mass flow controller 71 that is interposed into the gas pipe 7, into the vacuum chamber 1 of the vacuum atmosphere. The self-ionized sputtering apparatus SM has a conventional controller Cr that includes a microcomputer, a sequencer or the like and integrally controls actuations of each type of devices such as the first and second DC power sources E1, E2, the high-frequency bias power source 61 and the mass flow controller 71. In the following, the film deposition method will be described in detail based on an example of the deposition of the Cu film using the self-ionized sputtering apparatus SM.

After the target 2 that is made of a copper of predetermined purity and is mounted on the substrate Sw is positioned and held in the vacuum chamber 1 by the stage 5, an evacuating device, which is not shown, evacuates an interior of the vacuum chamber 1 to a predetermined pressure (for example, 10⁻⁵ Pa). When the pressure in the vacuum chamber 1 reaches the predetermined value, Ar gas is introduced into the vacuum chamber 1 at a predetermined flow rate (for example, in a range of 10 sccm to 20 sccm) by controlling the mass flow controller 71. Then, the positive potential (for example, in a range of 5V to 100V) is applied to the reflector plate 4 by the second Dc power source E2, a predetermined electric power (for example, in a range of 18 kW to 24 kW) with the negative potential is supplied to the target 2 by the first DC power source E1, and, in addition, the high-frequency bias power (for example, in a range of 50 W to 1300 W) is supplied to the stage 5 by the high-frequency bias power source 61 through the impedance matching device 62. As a result, the plasma is generated in the lower space of the target 2, and the plasma is confined in the lower space by a leakage magnetic field from the magnet unit 3. In this state, when the introduction of the sputtering gas is stopped by controlling the mass flow controller 71, a self-holding discharge under low pressure of plasma is generated. Ions or the like of the sputtering gas in the plasma collide with the sputtered surface 21b of the target 2, are sputtered and are scattered from the target 2. Both Cu atoms appropriately reflected on the reflector plate 4 and ionized Cu ions are adhered to and accumulated on the inner surface Sf1, Sf2 of each micro-recessed part Sf while being directed with strong straightness and attracted to the surface of the substrate Sw, and a Cu film is deposited.

In the embodiment, when the high-frequency bias power is supplied to the stage 5 by the high-frequency bias power source 61 during the deposition of the Cu film, the switching elements (not shown) of the pulse generating circuit are controlled to turn on and off, the high-frequency bias power at the predetermined frequency is intermittently supplied, and, in addition, the high-frequency bias power is separately supplied at two stages of which one is large and the other is small (referred to FIG. 2). In other words, the high-frequency bias power is set to a first electric power (for example, in a range of 10 W to 100 W, preferably 50 W) at the beginning of the deposition of the Cu film (a first step), and after a predetermined time has elapsed, the high-frequency electric power is changed to a second electric power (for example, in a range of 500 W to 900 W, preferably 700 W) larger than the first electric power from the first electric power and is continuously supplied (a second step). Electric power supply times of the first and second electric powers can be set so that a film thickness of the Cu film to be deposited is standard and a ratio of a film thickness deposited by supplying the first electric power to that deposited by supplying the second electric power becomes, for example, 1:3. In addition, the frequency when the high-frequency bias power is intermittently supplied is set in a range of 1 kHz to 20 kHz, and a duty ratio (an ON time in one cycle) when the high-frequency bias power is intermittently supplied is set in a range of 50% to 90%. It should be noted that if the frequency is lower than 1 kHz or the duty ratio is smaller than 50%, an adhesion effect to the inner side surface Sf1 by the sputtering cannot be obtained sufficiently, and if the duty ratio is larger than 90%, uniformity in the surface of a film-thickness distribution will be impaired. Furthermore, if the frequency is higher than 20 kHz, there will be an issue that voids (vacancies) occur in each micro-recessed part Sf when Cu wiring is embedded by a plating method in a subsequent step.

Accordingly, the particles scattered from the target 2 preferentially adhere to and accumulate on the inner bottom surface Sf2 of each micro-recessed part Sf at the beginning time of the deposition of the Cu film, and the Cu film is deposited. Furthermore, when the high-frequency bias power is changed from the first electric power to the second electric power, the Cu film on the inner bottom surface Sf2 is re-sputtered by high Vdc generated instantaneously each time the high-frequency bias power is supplied in addition to the Cu atoms and ionized Cu ions from a side of the target 2. The re-sputtered particles adhere to and accumulate on the inner side surface Sf1 from a reverse direction (down) to the side of the target 2. Accordingly, even if the inner side surface Sf1 of each micro-recessed part Sf is not flat, the Cu film of the predetermined thickness can be deposited on the inner side surface Sf1 with continuity and good coverage. At this time, if the supplied high-frequency bias power is changed, a height position from the inner bottom surface Sf2 of each micro-recessed part Sf, to which re-sputtered particles mainly adhere, can be regulated.

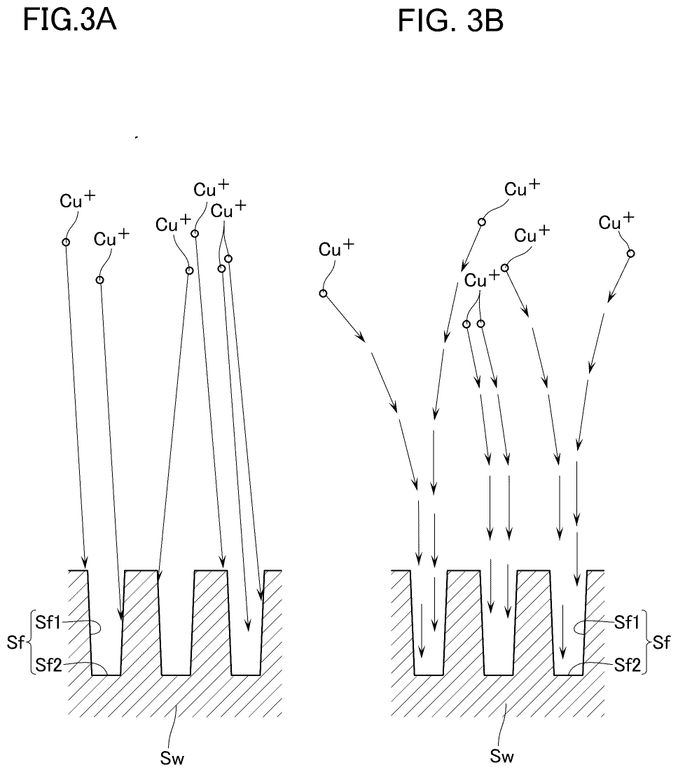

In addition, when the Cu film is sputtered as aforementioned, occurrence of overhang can be suppressed as much as possible. The reason for this is as follows: As in the conventional method, when the high-frequency bias power is continuously supplied to the stage 5 while the positive potential is applied to the reflector plate 4, the Cu ions are directly attracted to the substrate Sw with strong straightness. However, as shown in FIG. 3A, at this time, some Cu ions are attracted not only in the vertical direction to the surface of the substrate Sw (upper surface) but also at an inclined state to the vertical direction (in other words, to be incident diagonally to the substrate Sw). Furthermore, the electric field is liable to concentrate in corners between the surface of the substrate Sw and the inner side surface Sf1 of each micro-recessed part Sf.

In contrast, in the embodiment, such electric field concentration can be suppressed by intermittently supplying the high-frequency bias power. Besides, as shown in FIG. 3B, in each OFF state of the supply of the high-frequency electric bias power, the attraction of the Cu ions to the substrate Sw is instantaneously eliminated, and tracks of the Cu ions are corrected so as to be he vertical direction to the surface of the substrate Sw, whereby the occurrence of the overhang is considered to be suppressed as much as possible. As a result, even if the inner side surface Sf1 of each micro-recessed part Sf is not flat, the Cu film with a relatively thin thickness (for example, in a range of 200 Å to 700 Å) can be deposited on the inner side surface Sf1 with continuity and good coverage. It should be noted that the aforementioned film deposition method was also confirmed to be effective when the target 2 is made of tantalum of predetermined purity and a Ta film is deposited on the inner surface Sf1, Sf2 of each micro-recessed part Sf. In addition, it was confirmed that when the high-frequency bias power is intermittently supplied at a predetermined frequency, and, in addition, the potential applied to the reflector plate 4 is changed, a film deposition rate can be changed in accordance with the potential change. Furthermore, it was confirmed that the film-thickness distribution in the surface of the substrate Sw can be made approximately constant independent of the potential applied to the reflector plate 4.

In order to confirm the aforementioned effects, the Cu film was deposited using the self-ionized sputtering apparatus SM as shown in FIG. 1. The substrate Sw was used as the one formed by the following steps: A silicon oxide film was formed on an entire surface of a Si wafer of φ 300 mm; subsequently, a plurality of micro-recessed parts Sf (70 nm wide and 210 nm deep) was patterned and formed; and then TaN and Ta of a film thickness of 13 nm were deposited on the inner surface Sf1, Sf2 of each micro-recessed part Sf. The target 2 was used as the one made of Cu with a composition ratio of 99.9999%. The film deposition conditions were as follows: A distance between the sputtered surface 21b of the target 2 and the substrate Sw was set to 300 mm; the electric power supplied to the target 2 was set to 16 kW (electric current 38 A); the voltage supplied to the reflector plate 4 was set to 100V; the flow rate of the argon gas introduced at the beginning was set to 10 sccm; and the Cu film was deposited only for the predetermined time while a temperature of the substrate Sw was maintained at room temperature or cooler.

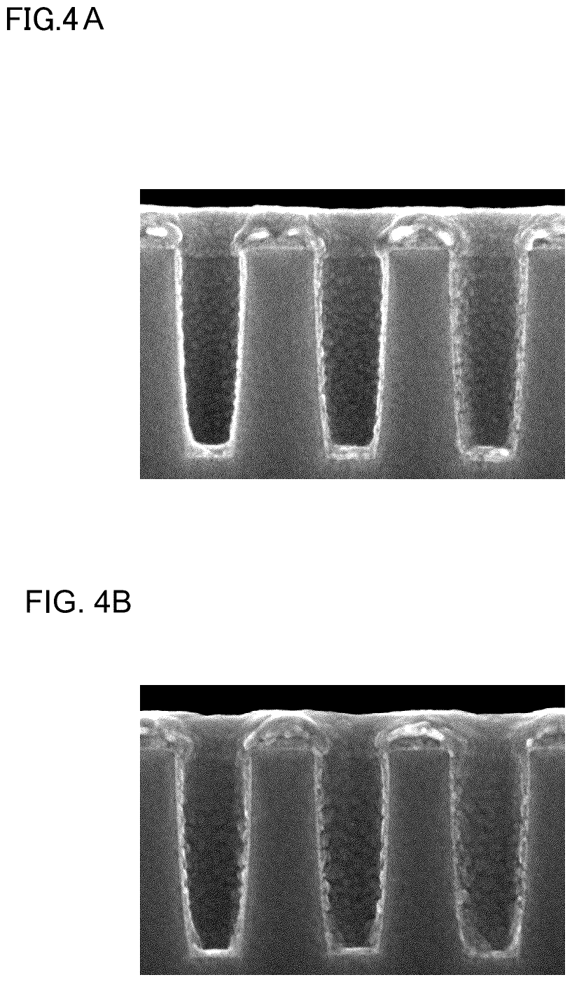

In Comparison Experiment No. 1, the high-frequency bias power was set to 700 W and supplied continuously from the beginning of the film deposition. In contrast, in Invention Experiment No. 1, the frequency and the duty ratio were set to 1 kHz, 50%, respectively, and the high-frequency bias power was intermittently supplied. In addition, at the beginning of the film deposition, the high-frequency bias power was set to 50 W, the Cu film was deposited only for a predetermined time, subsequently, the high-frequency bias power was changed to 700 W, and then the Cu film was deposited again. FIGS. 4A, 4B are SEM images at a central part of the substrate Sw in Invention Experiment No. 1, Comparison Experiment No. 1, respectively. In Comparison Experiment No.1, the film thickness on the surface of the substrate Sw was 36 nm, the film thickness on the inner bottom surface Sf2 of each micro-recessed part Sf was 7.1 nm, an average value of the film thickness on the inner side surface Sf1 was 6.2 nm, and the overhang (in other words, the film thickness of the Cu film protruding toward an inside of each micro-recessed part Sf at a position where the surface of the substrate Sw and an upper end of the inner side surface Sf1 of each micro-recessed part Sf intersect) was 19.1 mm (referring to FIG. 4B). In contrast, in Invention Experiment No. 1, the film thickness on the surface of the substrate Sw was 39.7 nm, the film thickness on the inner bottom surface Sf2 of each micro-recessed part Sf was 12.7 nm, the average value of the film thickness on the inner side surface Sf1 of each micro-recessed part Sf was 7.5 nm, and the overhang was 13.9 nm. Compared with Comparison Experiment No. 1, it was confirmed that side coverage is improved, in addition, the overhang is suppressed, asymmetry is small, and the Cu film is deposited on the inner side surface Sf1 with continuity (referred to FIG. 4A).

Next, in Invention Experiment No. 2, the frequency was set to 10 kHz, the duty ratios were set to 10%, 50% and 90%, respectively, and the other deposition conditions were set to the same as in Invention Experiment No. 1. The Cu film was deposited and analyzed by a SEM image. In a case of the duty ratio of 10%, compared with Invention Experiment No. 1, it is confirmed that there are some portions that have a thinner film thickness on the inner bottom surface Sf2 depending on positions in the surface of the substrate Sw, and that the overhang is not sufficiently small. On the other hand, in both cases where the duty ratio was 50% and 90%, respectively, it was confirmed that the film thickness on the inner side surfaces Sf1 is at least 1 nm thicker and the overhang is at least 5 nm smaller than in Comparison Experiment No. 1. Furthermore, in Invention Experiment No. 3, the duty ratio was set to 50%, the frequency was set to 1 kHz, 10 kHz and 20 kHz, respectively, the other deposition conditions were set to the same as in Invention Experiment No. 1, and the Cu film was deposited. It was confirmed that if the frequency is in the range of 1 kHz to 20 kHz, the film thickness on the inner side surface Sf1 is at least 1 nm thicker than that in Comparison Experiment No.1 and the Cu film is deposited with continuity. It was also confirmed that the overhang is at least 5 nm smaller and the asymmetry is smaller.

In addition, a case where the high-frequency bias power was set to 30 W and continuously supplied from the beginning of the film deposition and the Cu film was deposited (Invention Experiment No. 4) and a case where the high-frequency bias power was set to 0 W and the Cu film was deposited (Comparison Experiment No. 2) were compared. As a result, it was confirmed that the film thickness on the inner bottom surface Sf2 of each micro-recessed part Sf is approximately same in both Invention Experiment No.4 and Comparison Experiment No. 2. On the other hand, it was also confirmed that the film thickness on the inner side surface Sf1 of each micro-recessed part Sf in Invention Experiment No. 4 is improved by a factor of 1.3 to 1.6 and the overhang is suppressed as compared with Comparison Experiment No. 2. In view of the above, it is understood that the supply of the high-frequency bias power in the relatively small first electric power at the beginning of the film deposition allows the metal film to be preferentially deposited on the inner bottom surface Sf2 of each micro-recessed part Sf.

Although the embodiment of the invention is described referring to the figures in the above, various modifications are possible within a scope of the technological concept of the invention. The aforementioned embodiment is described as an example in which the conventional pulse generating circuit is provided at the high-frequency bias power source 61 and is turned on and off at the predetermined frequency. However, as long as the high-frequency bias power source can intermittently supply the high-frequency bias power to the stage 5, the high-frequency electric power is not limited to the aforementioned one. In addition, although the embodiment is described as an example in which the electron matcher is used as an impedance matching device 62, as long as the impedance matching device can match the impedance of the plasma with the impedance of the side of the high-frequency bias power source 61 in a short time such as a few ms, the impedance matching device is not limited to the aforementioned electron matcher. Furthermore, although the embodiment exemplifies the metal films such as the Cu film and the Ta film, the metal films are not limited to these metal films. For example, the target 2 is made of the tantalum of predetermined purity, a reactive gas such as nitrogen, oxygen or both is also introduced during the deposition, and the invention can be adapted to the deposition of nitride, oxide and oxynitride films (a Ta-containing film) on the inner surface Sf1, Sf2 of each micro-recessed part Sf.

### Explanation of Symbols

SM Self-ionized sputtering apparatus
Sw Substrate (Object to be deposited)
Sf Micro-recessed part
Sf1 Inner side surface
Sf2 Inner bottom surface
1 Vacuum chamber
2 Target
4 Reflector plate
5 Stage
61 High-frequency bias power source
62 Electron matcher (Impedance matching device)
7 Gas pipe (component of gas introducer)

1. A film deposition method for depositing a metal film on an inner surface of each of a plurality of micro-recessed parts formed in a surface of an object to be deposited, the object being disposed in a vacuum chamber, comprising,
a step of sputtering a target made of a metal while generating a self-holding discharge under low pressure of plasma after successively introducing the sputtering gas containing a rare gas into a vacuum chamber of a vacuum atmosphere, supplying an electric power with a negative potential to the target, and then stopping the introduction of the sputtering gas;
a step of applying a positive potential to a reflector plate disposed to surround a space between the object to be deposited and the target; and
a step of supplying a high-frequency bias power from a high-frequency bias power source to a stage, on which the object to be deposited is mounted, through an impedance matching device that matches an impedance of the plasma with an impedance on a side of the high-frequency bias power source,
wherein in the supply of the high-frequency bias power, an electron matcher having at least one variable reactor to be electronically controlled is used as an impedance matching device and the high-frequency bias power is intermittently supplied to the stage at a predetermined frequency.

2. The film deposition method as claimed in claim 1, wherein the supply of the high-frequency bias power comprises a first step of setting the high-frequency electric power to a first electric power at the beginning of the deposition and preferentially depositing the metal film on the inner bottom surface of each micro-recessed part, and a second step of changing to a second electric power larger than the first electric power and supplying the high-frequency electric power.

3. The film deposition method as claimed in claim 1, wherein the frequency when the high-frequency bias power is supplied intermittently is set in a range of 1 kHz to 20 kHz.

4. The film deposition method as claimed in claim 1, wherein a duty ratio when the high-frequency bias power is supplied intermittently is set in a range of 50% to 90%.

5. The film deposition method as claimed in claim 2, wherein the metal film is either a Cu-containing film formed as a seed layer or a Ta-containing film formed as an underlayer of the Cu-containing film.

6. A film deposition apparatus for depositing a metal film on an inner surface of each of a plurality of micro-recessed parts formed in a surface of an object to be deposited, the object being disposed in a vacuum chamber, comprising,
a gas introducer introducing a sputtering gas containing a rare gas into a vacuum chamber of a vacuum atmosphere;
a sputtering power source that supplies an electric power with a negative potential to a target made of a metal;
a reflector plate that is disposed to surround a space between the object to be deposited and the target and to which a positive potential is applied; and
a stage on which the object to be deposited is mounted and to which a high-frequency bias power is supplied from a high-frequency bias power source through an impedance matching device that matches an impedance of a plasma with an impedance on a side of the high-frequency bias power source,
wherein the film deposition apparatus is configured that after the plasma is generated in a space in front of a sputtered surface of the target, while the introduction of the sputtering gas is stopped to generate a self-holding discharge under low pressure of pasma, the target is sputtered, and
wherein the impedance matching device is configured by an electron matcher having at least one variable reactor to be electronically controlled, the impedance matching device being configured that the high-frequency bias power source intermittently supplies the high-frequency bias power.
